(19) United States
(12) Patent Application Publication
(10) Pub. No.: US 2016/0086828 A1
(43) Pub. Date: Mar. 24, 2016

(54) MAGAZINE AND PROCESS EQUIPMENT INCLUDING THE SAME

(71) Applicant: Samsung Electronics Co., Ltd., Suwon-si (KR)

(72) Inventors: Yi-sung Hwang, Chungcheongnam-do (KR); Jun-young Ko, Chungcheongnam-do (KR); Dong-woo Kang, Gwangmyeong-si (KR); Se-yeoul Park, Chungcheongnam-do (KR)

(21) Appl. No.: 14/691,917

(22) Filed: Apr. 21, 2015

(30) Foreign Application Priority Data
Sep. 18, 2014 (KR) 10-2014-0124633

(51) Int. Cl. H01L 21/673

(52) U.S. Cl. CPC H01L 21/6732; H01L 21/67333

(57) ABSTRACT

A magazine includes a main body unit having a front side and a rear side, at least one of which is open, a plurality of slots formed inside two sidewalls of the main body unit, and at least one support member extending to the two sidewalls of the main body unit in a first direction.

### CROSS-REFERENCE TO RELATED APPLICATION

This application claims priority under 35 USC §119 to Korean Patent Application No. 10-2014-0124633, filed on Sep. 18, 2014, in the Korean Intellectual Property Office, the disclosure of which is incorporated herein in its entirety by reference.

### BACKGROUND

The inventive concepts relate to a magazine including a support member and a process equipment including the magazine.

A semiconductor package manufacturing process may involve a front-end process, such as a chip bonding process and a wire bonding process, and a back-end process, such as a molding process, a cleaning process, a trimming process, a forming process, a curing process, or an ink marking process. A magazine may be used to stack and contain strip members and transfer the strip members between the processes while protecting the strip members from mechanical, physical, and electrical impacts.

### SUMMARY

The inventive concepts provide a magazine and a process equipment including the same, which may stably protect a strip member for a semiconductor package.

According to an example embodiment of the inventive concepts, a magazine may include: a main body unit having a front side, a rear side and a first sidewall and a second sidewall, wherein at least one of the front surface and the rear surface of the main body unit is open, a plurality of slots inside each of the first and second sidewalls of the main body unit, and at least one support member between the slots and configured to extend from the first sidewall of the main body to the second sidewall of the main body unit in a first direction. Each of the slots may extend in a second direction perpendicular to the first direction, and a length of each of the slots in the second direction may be greater than a length of the support member in the second direction.

In some embodiments, the support member may have a plate form,

In some embodiments, at least one of the front side and the rear side of the support member may have a V shape in plan view.

According to an example embodiment of the inventive concepts, a magazine may include: a main body unit including first and second sidewalls opposed to each other, a plurality of slots inside each of the first and second sidewalls of the main body unit, and a support member between the slots and including at least one support stick configured to connect insides of the first and second sidewalls of the main body unit.

In some embodiments, each of the slots may extend in a first direction. A length of each of the slots in the first direction may be greater than a length of the support member in the first direction.

In some embodiments, the magazine further comprises a plurality of protrusions extending in the first direction inside the two sidewalls of the main body unit and to define the slots. The support member is on the protrusions.

In some embodiments, a thickness of each of the protrusions may be greater than a thickness of the support member.

In some embodiments, a top surface of each of the protrusions may be at a higher level than a top surface of the support member.

In some embodiments, a front side and a rear side of the support member may be spaced apart from at least one of an open front surface and an open rear side of the main body unit.

In some embodiments, the support member may comprise an insulating material. The support member may comprise a heat-resistant member.

In some embodiments, the support stick may have a cylindrical structure or a semi-cylindrical structure. The support stick may be an insulating wire.

In some embodiments, the support stick may extend to connect a front side portion of one sidewall of the main body unit and a rear side portion of the other sidewall opposite to the one sidewall of the main body.

In some embodiments, the at least one support stick may include: a first support stick configured to extend to connect a front side portion of the first sidewall of the main body unit and a rear side portion of the second sidewall of the main body unit, and a second support stick configured to extend to connect a rear side portion of the first sidewall of the main body unit and to a front side portion of the second sidewall of the main body unit.

According to an example embodiment of the inventive concepts, a magazine may include: a main body unit having an open front side, an open rear side, a first sidewall and a second sidewall opposed to the first sidewall, first protrusions inside the first sidewall of the main body unit and second protrusions inside the second sidewall of the main body unit, and a support member configured to connect the first and second protrusions and disposed in a plane defined by the first direction and a second direction perpendicular to the first direction.

In some embodiments, the support member may include edge portion and a central portion. A length of the edge portion of the support member in a first direction is greater than a length of a central portion of the support member.

In some embodiments, a length of the support member in the second direction may be smaller than a length of the main body unit in the second direction.

In some embodiments, a front side of the support member may be spaced a first distance apart from the front side of the main body unit in the first direction. A rear side of the support member may be spaced a second distance apart from the rear side of the main body unit in the first direction. The first distance may be substantially equal to the second distance.

In some embodiments, the magazine may further include a stopper disposed on at least one of the front side and the rear side of the main body unit.

### BRIEF DESCRIPTION OF THE DRAWINGS

Exemplary embodiments of the inventive concepts will be more clearly understood from the following detailed description taken in conjunction with the accompanying drawings in which:

FIG. 1 is a perspective view of a magazine according to an example embodiment of the inventive concepts;

FIGS. 2 and 3 are diagrams of stoppers, which may be included in the magazine of FIG. 1, according to some embodiments of the inventive concepts;

FIG. 4 is a front view of a magazine according to an example embodiment of the inventive concepts;

FIG. 5 is a partial enlarged view of a region C of FIG. 4;

FIGS. 6 and 7 are diagrams for explaining functions of a support member according to an example embodiment of the inventive concepts;

FIG. 8 is a plan view of a magazine according to an example embodiment of the inventive concepts;

FIG. 9 is a plan view of a magazine according to an example embodiment of the inventive concepts;

FIG. 10A is a plan view of a magazine according to an example embodiment of the inventive concepts;

FIGS. 10B and 10C are vertical cross-sectional views corresponding to a line I-I′ of FIG. 10A;

FIGS. 11 through 14 are plan views of magazines according to example embodiments of the inventive concepts;

FIG. 15A is a perspective view of a process equipment including magazines according to example embodiments of the inventive concepts;

FIG. 15B is a schematic diagram of the process equipment of FIG. 15A; and

FIG. 16 is a schematic diagram of a process equipment including magazines according to example embodiments of the inventive concepts.

### DETAILED DESCRIPTION OF EMBODIMENTS

The inventive concepts will now be described more fully hereinafter with reference to the accompanying drawings, in which exemplary embodiments of the inventive concepts are shown. This inventive concept may, however, be embodied in different forms and should not be construed as limited to the embodiments set forth herein. Rather, these embodiments are provided so that this disclosure is thorough and complete and fully conveys the scope of the inventive concepts to one skilled in the art. Like reference numerals in the drawings denote like elements, and thus their description will be omitted.

It will be understood that although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification and will not be interpreted in an idealized or overly formal sense unless explicitly so defined herein.

Unless explicitly defined in a specific order herein, respective steps described in the present invention may be performed otherwise. That is, the respective steps may be performed in a specified order, substantially at the same time, or in reverse order.

Variations from the shapes of the illustrations as a result, for example, of manufacturing techniques and/or tolerances, are to be expected. Thus, embodiments of the inventive concepts should not be construed as limited to the particular shapes of regions illustrated herein but are to include deviations in shapes that result, for example, from manufacturing.

As used herein, expressions such as “at least one of,” when preceding a list of elements, modify the entire list of elements and do not modify the individual elements of the list.

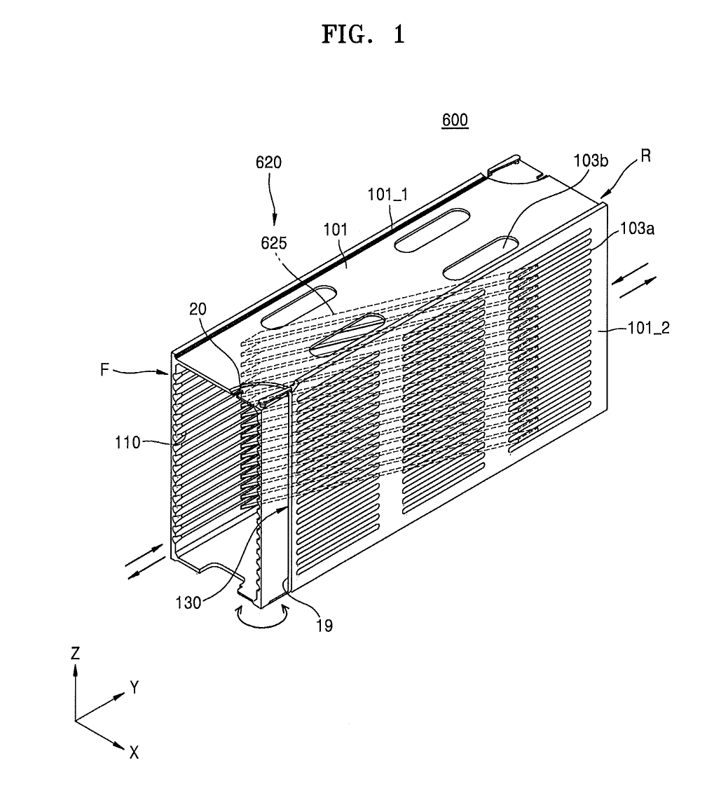

FIG. 1 is a perspective view of a magazine 600 according to an example embodiment of the inventive concepts.

Referring to FIG. 1, the magazine 600 may include a main body unit 101, a plurality of first and second through holes 103a and 103b, a plurality of slots 110, a plurality of support members 620, and a stopper 130.

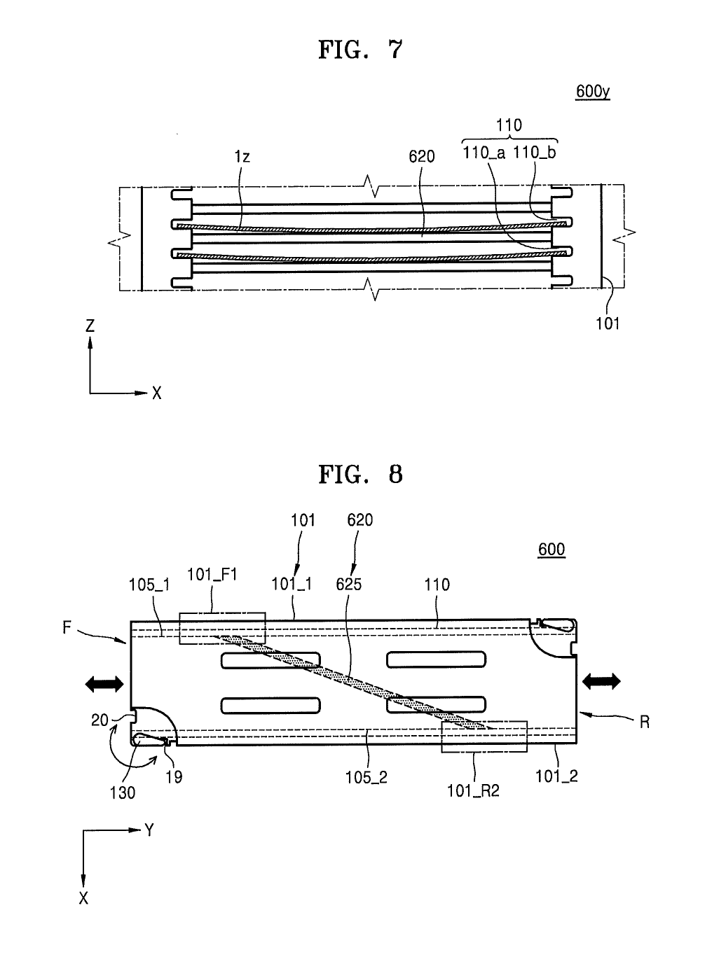

At least one of a front side F and a rear side R of the main body unit 101 may be open so that a strip member (not shown) may be loaded into and unloaded from the main body unit 101. The strip member will be described in detail herein with reference to FIGS. 6 and 7.

In some embodiments, when any one of the front side F and the rear side R of the main body unit 101 is open and the other one thereof is closed, the strip member may be loaded into and unloaded from the open side. In other embodiments, when both the front side F and the rear side R of the main body unit 101 are open, the strip member may be loaded into any one of the front side F and the rear side R and unloaded from the other one thereof.

At least ones of a plurality of first through holes 103a and a plurality of second holes 103b may be formed in at least one of a top side, a bottom side, and two sidewalls of the main body unit 101. The first and second through holes 103a and 103b may serve as ventilation holes or heat radiation holes during storage and transfer of the strip member.

The slots 110 may function to support an edge region of the strip member and contain the strip member. The slots 110 may be disposed apart from one another in a third direction (Z-axial direction). Each of the slots 110 may extend in a second direction (Y-axial direction).

Each of the support members 620 may be disposed between the slots 110 and extend from a first sidewall 101_1 of the main body unit 101 to a second sidewall 101_2 of the main body unit 101 in a horizontal plane (XY plane).

Each of the support members 620 may have a stick shape. That is, each of the support members 620 may include at least one support stick 625. In some embodiments, the support stick 625 may be an insulating wire.

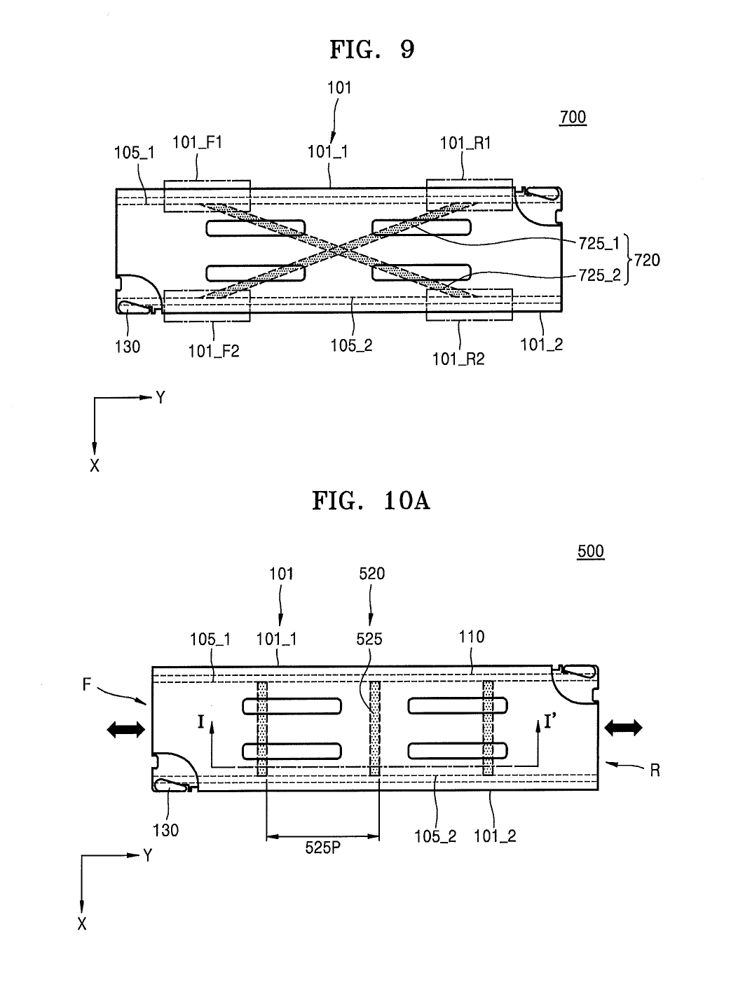

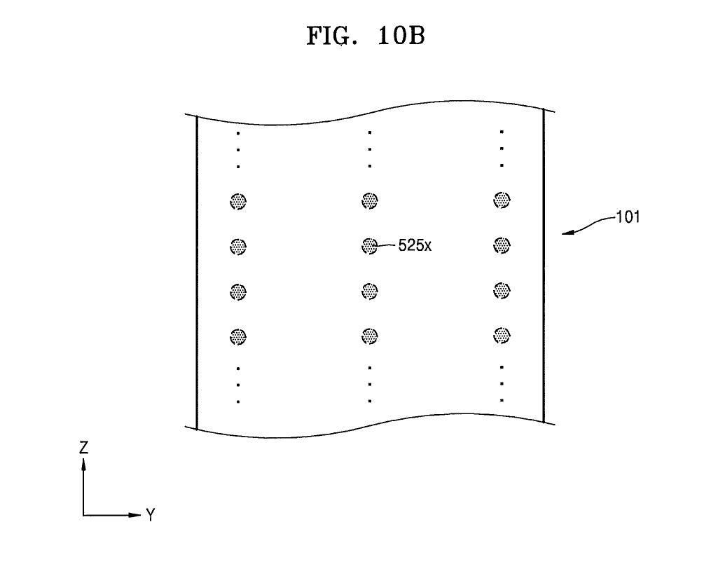

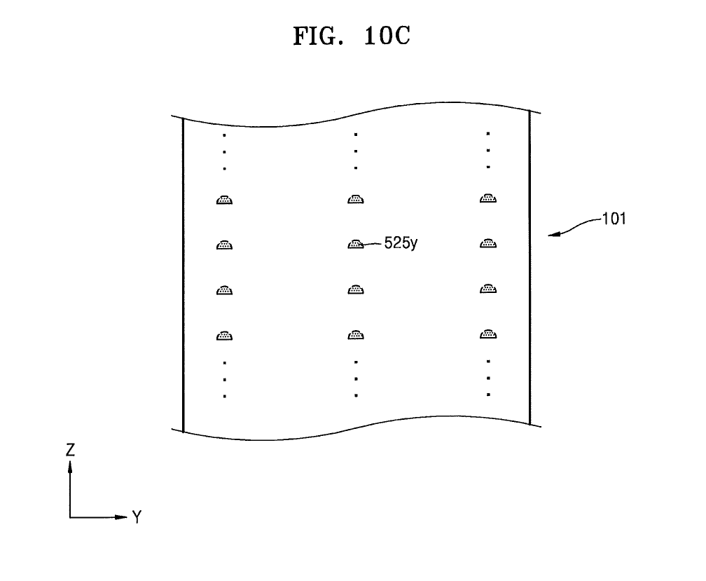

The support member 620 may include, for example, one support stick 625 between slots 110 in a horizontal plan view (XY plane), but the inventive concept is not limited thereto. In some embodiments, the support member 620 may include a plurality of support sticks between slots 110 in a horizontal plan view (XY plane) as described herein with reference to FIGS. 9 through 10C.

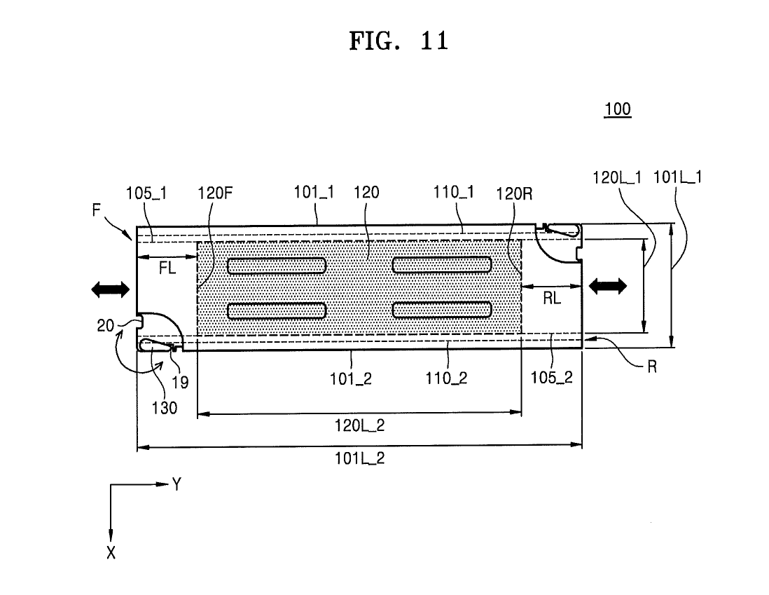

In addition, FIG. 1 illustrates a case in which the support member 620 according to the present embodiment has a stick shape, but the inventive concept is not limited thereto. For example, the support member 620 may have a plate form as shown in FIGS. 11 through 14.

In some embodiments, a sectional structure of the support stick 625 on a vertical plane (a plane including a Z-axis) may have a polygonal shape, such as a rectangular shape as shown in FIG. 1. However, the sectional structure of the support stick 625 is not limited to the rectangular shape and may have various other shapes, such as an elliptical shape or other polygonal shapes, which will be described in detail later with reference to FIGS. 8 through 10C.

The support members 620 may prevent a sag in strip members contained in the slots 110 or separation of the strip members. The function of the support members 620 will be described in detail later with reference to FIGS. 6 and 7.

The stopper 130 may be a mechanical structure mounted on the magazine 600 to prevent strip members contained in the magazine 600 from being externally separated or damaged. The stopper 130 may be disposed on at least one of an open front side F or an open rear side R of the main body unit 101.

The strip members contained in the slots 110 may be put into an unlocked state or a locked state depending on a state of the stopper 130. When the stopper 130 is fixed to a first stopper susceptor 19 of the main body unit 101, the contained strip members may be put into an unlocked state. When the stopper 130 is fixed to a second stopper susceptor 20 of the main body unit 101, the contained strip members may be put into a locked state. In the locked state, the stopper 130 may prevent the strip members from being externally separated or damaged

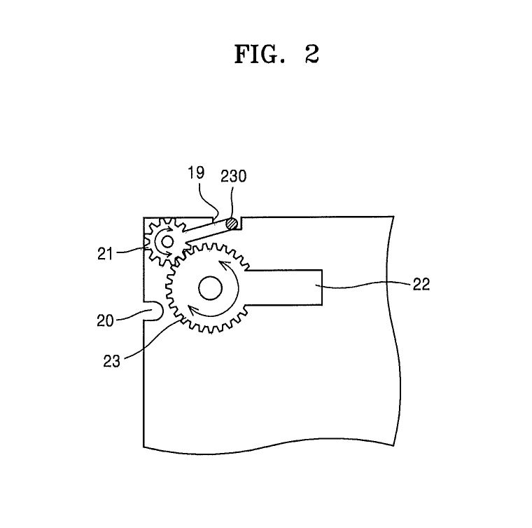

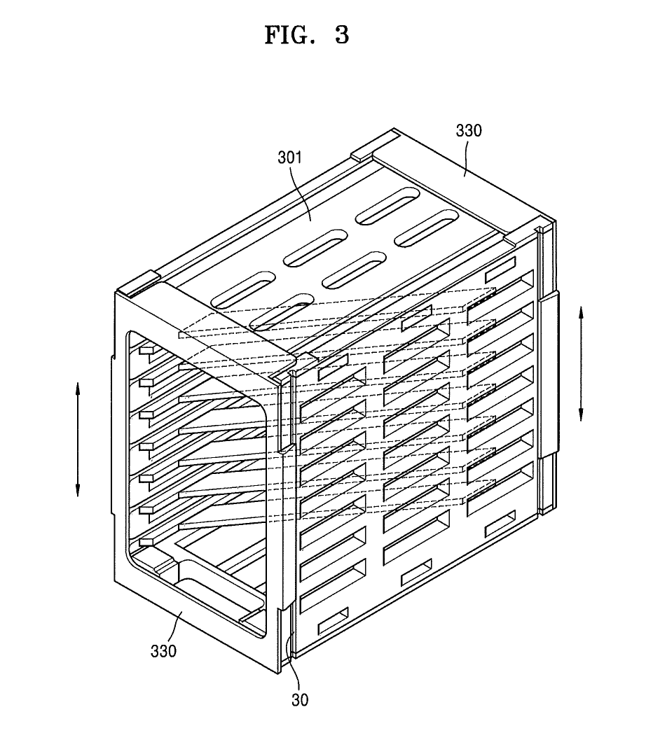

FIGS. 2 and 3 are diagrams of stoppers 230 and 330, which may be included in the magazine 600 of FIG. 1, according to some embodiments of the inventive concepts.

That is, the magazine 600 according to the present embodiment may include a stopper having other structures than the stopper 130 of FIG. 1. For example, as shown in FIG. 2, when a knob 22 rotates, an operating gear 23 combined with the knob 22 and a rotating gear 21 engaged with the operating gear 23 may rotate so that the stopper 230 may move from the first stopper susceptor 19 to the second stopper susceptor 20. In some embodiments, as shown in FIG. 3, guide grooves 30 may be formed in two sidewalls of a main body unit 301, and a stopper 330 having a cover shape may move along the guide grooves 30 and may open and close the opening of the main body unit 301. Each of the stoppers 230 and 330 shown in FIGS. 2 and 3 may be used for the magazine 600 according to the inventive concepts.

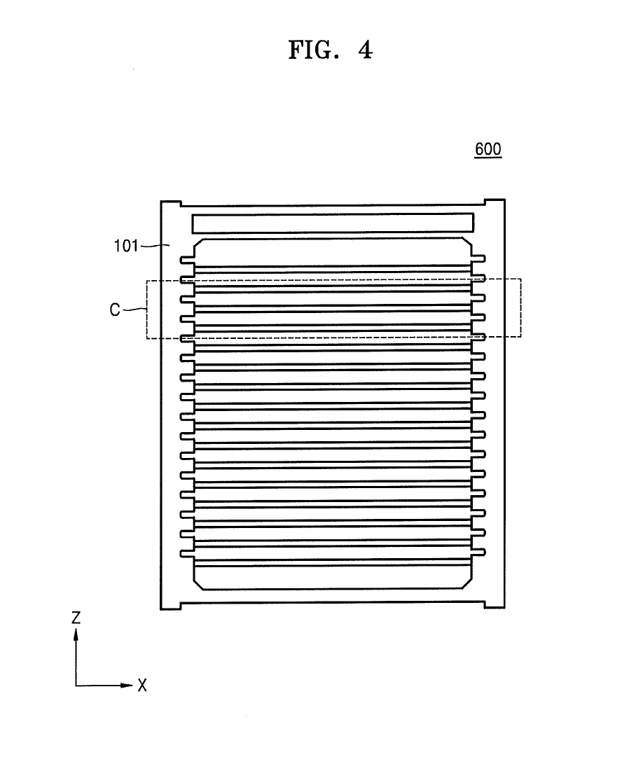

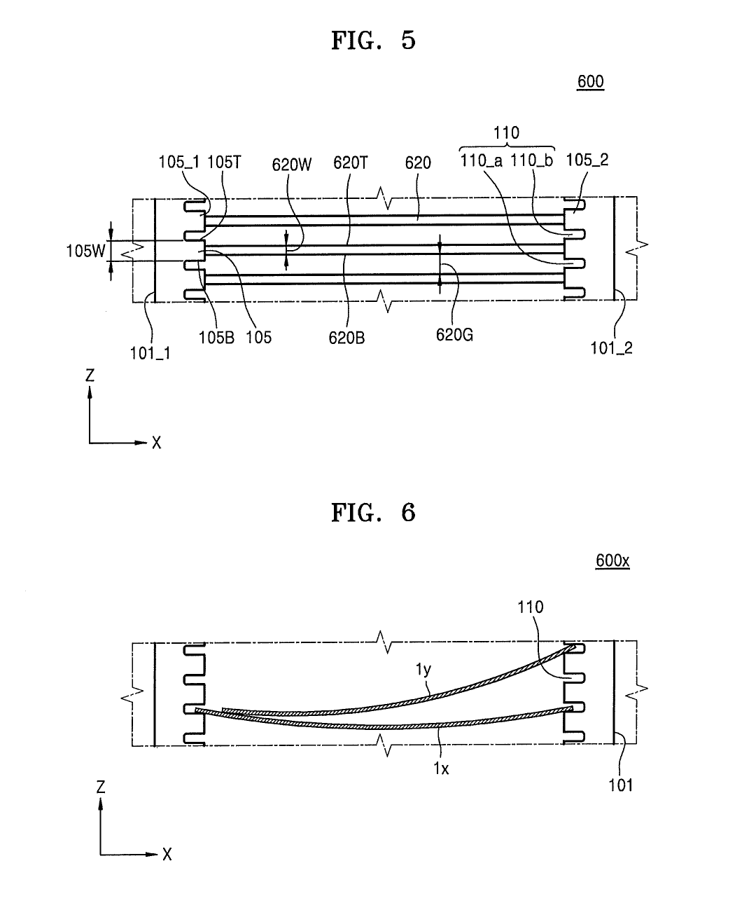

FIG. 4 is a front view of a magazine 600 according to an example embodiment of the inventive concept, and FIG. 5 is a partial enlarged view of a region C of FIG. 4.

Referring to FIGS. 4 and 5, a plurality of protrusions 105 may be formed inside two side sidewalls of a main body unit 101.

The protrusions 105 may be disposed apart from one another in a third direction (Z-axial direction). Slots 110 may be defined by spaces between the respective protrusions 105.

Each of the support members 620 may extend in a first direction (X-axial direction) between a first protrusion 105_1 disposed inside the first sidewall 101_1 of the main body unit 101 and a second protrusion 105_2 disposed inside the second sidewall 101_2 of the main body unit 101. Each of the support members 620 may be disposed between slots 110_{—}a and 110_{—}b disposed adjacent to one another in a third direction (Z-axial direction).

The support members 620 may be disposed apart from one another at first intervals 620G in the third direction (Z-axial direction). The first interval 620G between the support members 620 may be greater than a thickness of each strip member contained in each slot 110.

In some embodiments, a top surface 620T of each of the support member 620 may be at a lower level than a top surface 105T of each of the protrusions 105, and a bottom surface 620B of each of the support members 620 may be at a higher level than a bottom surface 10513 of each of the protrusions 105.

In some embodiments, each of the support members 620 may be disposed on a middle region of each of the protrusions 105. That is, a distance between each of the support members 620 and one slot 110_{—}a may be substantially the same as a distance between each of the support members 620 and other slot 110_{—}b.

In some embodiments, a width 620W of each of the support members 620 in the third direction (Z-axial direction) may be less than a width 105W of each of the protrusions 105 in the third direction (Z-axial direction). That is, a thickness 620W of each of the support members 620 may be less than a thickness of each of the protrusions 105.

As in the present embodiment, when each of the support members 620 is disposed in the middle region of each of the protrusions 105 and the width 620W of each of the support members 620 obtained in the third direction (Z-axial direction) is less than the width 105W of each of the protrusions 105 obtained in the third direction (Z-axial direction), a phenomenon where strip members are caught by the support members 620 may be reduced during the loading or unloading of the strip members.

FIGS. 6 and 7 are diagrams for explaining functions of a support member 620 according to an example embodiment of the inventive concepts. FIG. 6 illustrates a state in which strip members 1x and 1y are contained in slots 110 of a magazine 600x that does not include support members 620, and FIG. 7 illustrates a state in which strip members 1z are contained in slots 110 of a magazine 600y including support members 620.

Referring to FIG. 6, the strip members 1x and 1y may be contained in the magazine 600x.

Each of the strip members 1x and 1y may be, for example, a substrate, a circuit film, or a lead frame. Meanwhile, the substrate may refer to a printed circuit board (PCB) per se, or a semiconductor package manufactured by performing a chip bonding process and a wire bonding process on a substrate.

Two end portions of the strip member 1x may be supported by the slots 110 formed in the magazine 600x so that the strip member 1x may be contained in the magazine 600x. In this case, a central portion of the strip member 1x may greatly sag due to self-weight of the strip member 1x.

Furthermore, as a sag amount increases, portions of the strip member 1x supported by the slot 110 may be reduced so that at least one end portion of the strip member 1y may be separated from the slot 110.

When at least one end portion of the strip member 1y is separated, the strip member 1y may drop to a bottom side of the magazine 600x, breakage may occur due to overlap or collision between the strip members 1x and 1y. Thus, failures may occur in the strip members 1x and 1y.

Referring to FIG. 7, the strip members 1z may be contained in the magazine 600y.

Two end portions of each of the strip members 1z may be supported by each of the slots 110 formed in the magazine 600y so that the strip members 1z may be contained in the magazine 600y.

Each of the support members 620 may be disposed between the slots 110_{—}a and 110_{—}b disposed adjacent to each other in the third direction (Z-axial direction), and serve to support a central portion of the strip member 1z. That is, a sag in the central portion of the strip member 1z due to self-weight of the strip member 1z may be prevented by the support member 620 By preventing a sag in the strip member 1z, portions of two end portions of the strip member 1z, which are supported by the slot 110, may be sufficiently ensured to prevent at least one end portion of the strip member 1z from being separated from the slot 110.

FIG. 8 is a plan view of a magazine 600 according to an exemplary embodiment of the inventive concept. In FIG, 8, the same reference numerals are used to denote the same elements as in FIGS. 1 through 7, and repeated descriptions thereof are omitted for brevity.

In the present embodiment, a protrusion 105, a slot 110, and a support member 620, which are formed in a main body unit 101, are illustrated together to explain an internal structure of the main body unit 101.

Referring to FIG. 8, a front side F and a rear side R of the magazine 600 may have an open structure to load or unload strip members. Any one of the stoppers 130, 230, and 330 described above with reference to FIGS. 1 through 3 may be disposed in one edge region of each of the front side F and the rear side R of the magazine 600. Here, an example in which the stoppers 130 of FIG. 1 are formed will be described for brevity.

A first stopper susceptor 19 and a second stopper susceptor 20 may be formed in one edge region of the main body unit 101, in which each of the stoppers 130 is disposed. As described above with reference to FIG. 1, when the stopper 130 is fixed to the first stopper susceptor 19 of the main body unit 101, contained strip members may be put into an unlocked state. When the stopper 130 is fixed to the second stopper susceptor 20 of the main body unit 101, the contained strip members may be put into a locked state.

First and second protrusions 105_1 and 105_2 and first and second slots 110_1 and 110_2 may be formed inside the first sidewall 101_1 and the second sidewall 101_2 of the main body unit 101, respectively. The first and second protrusions 105_1 and 105_2 may extend in a second direction (Y-axial direction), and the first and second slots 110_1 and 110_2 may be defined by first and second the protrusions 105_1 and 105_2.

The support member 620 may be formed in the main body unit 101. In some embodiments, the support member 620 may include at least one support stick 625.

The support stick 625 may extend along a horizontal plane (XY plane) between the first protrusion 105_1 disposed inside the first sidewall 101_1 of the main body unit 101 and the second protrusion 105_2 disposed inside the second sidewall 101_2 of the main body unit 101. Specifically, the support stick 625 may extend to connect the first protrusion 105_1 formed inside a front portion 101_F1 of the first sidewall 101_1 of the main body unit 101 and the second protrusion 105_2 formed inside a rear portion 101_R2 of the second sidewall 101_2 of the main body unit 101.

The support stick 625 may have various sectional structures in a vertical plan view (a plane including a Z-axis). For example, a sectional structure of the support stick 625 may have a polygonal shape, such as a rectangular shape, as shown in FIG. 1. As another example, the sectional structure of the support stick 625 may have a circular shape similar to the support stick 525x shown in FIG. 10B, or a semi-circular shape similar to the support stick 525y shown in FIG. 10C. However, the sectional structure of the support stick 625 is not limited thereto and may have various shapes, such as an elliptical shape or other polygonal shapes.

When the support member 620 includes the support stick 625 and is formed at an angle to a first direction (X-axial direction), a contact area between the strip member and the support member 620 may be reduced during the containing of the strip member, thereby preventing a failure in the strip member. Also, a phenomenon where the strip member is caught by the support member 620 may be reduced during the loading and unloading of the strip member.

FIG. 9 is a plan view of a magazine 700 according to an example embodiment of the inventive concept. In FIG. 9, the same reference numerals are used to denote the same elements as in FIGS. 1 through 8, and repeated descriptions thereof are omitted for brevity.

Referring to FIG. 9, a support member 720 including support sticks 725_1 and 725_2 may be formed in a main body unit 101.

A first support stick 725_1 may extend to connect a second protrusion 105_2 formed inside a front portion 101_F2 of a second sidewall 101_2 of the main body unit 101 and a first protrusion 105_1 formed inside a rear portion 101_U of a first sidewall 101_1 of the main body unit 101. A second support stick 725_2 may extend to connect the first protrusion 105_1 formed inside a front portion 101_F1 of the first sidewall 101_1 of the main body unit 101 and the second protrusion 105_2 formed inside a rear portion of 101_R2 of the second sidewall 101_2 of the main body unit 101.

FIG. 10A is a plan view of a magazine 500 according to an example embodiment of the inventive concept, and FIGS. 10B and 10C are vertical cross-sectional views corresponding to a line I-I′ of FIG. 10A.

In FIGS. 10A through 10C, the same reference numerals are used to denote the same elements as in FIGS. 1 through 9, and repeated descriptions thereof are omitted for brevity.

Referring to FIGS. 10A through 10C, the magazine 500 may have a structure similar to the magazine 600 described with reference to FIGS. 1 through 8 except for a structure of a support member 520.

A support member 520 including a plurality of support sticks 525 may be formed in a main body unit 101. In some embodiments, each of the support sticks 525 may be an insulating wire.

Each of the support sticks 525 may extend in a first direction (X-axial direction) between a first protrusion 105_1 formed inside a first sidewall 101_1 of the main body unit 101 and a second protrusion 105_2 formed inside a second sidewall 101_2 of the main body unit 101.

In some embodiments, the support sticks 525 may be disposed in a second direction (Y-axial direction) and spaced apart from one another at constant pitches 525P. The support sticks 525 may be spaced apart from one another at the constant pitches 525P, but the inventive concept is not limited thereto. That is, the support sticks 525 may be disposed apart from one another in the second direction (Y-axial direction) at different intervals.

The support sticks 525 may have various structures in a vertical plan view (YZ plane).

In some embodiments, the support stick 525 may have a cylindrical structure having a circular vertical-plane (YZ-plane) sectional structure, like the support stick 525x shown in FIG. 10B.

In some other embodiments, the support stick 525 may have a semi-cylindrical structure having a semi-circular vertical-plane (YZ-plane) sectional structure, like the support stick 525y shown in FIG. 10C.

However, the vertical plane (YZ plane) sectional structure of the support sticks 525 is not limited thereto and may have various shapes, such as an elliptical shape or a polygonal shape.

When the support member 520 includes the support sticks 525 as in the present embodiment, a contact area between a strip member and the support member 520 may be reduced during the containing of the strip member, thereby preventing a failure in the strip member.

FIGS. 11 through 14 are plan views of magazines 100, 200, 300, and 400 according to example embodiments of the inventive concept.

In FIGS. 11 through 14, the same reference numerals are used to denote the same elements as in FIGS. 1 through 10C, and repeated descriptions thereof are omitted for brevity.

Each of the magazines 100, 200, 300, and 400 shown in FIGS. 11 through 14 may have a structure similar to the magazine 600 described with reference to FIGS. 1 through 8 except for a plane structure of each of support members 120, 220, 320, and 420. Specifically, the support member 620 described with reference to FIG. 8 may have a stick shape, while the support members 120, 220, 320, and 420 of FIGS. 11 through 14 may have a plate form.

Referring to FIG. 11, a front side F and a rear side R of the magazine 100 may have an open structure to load or unload a strip member. Stoppers 130 may be respectively located in one edge regions of the front side F and the rear side R of the magazine 100. The support member 120 may be formed in a main body unit 101. The support member 120 may extend along a horizontal plane (XY plane) between a protrusion 105_1 disposed in one sidewall 101_1 of the main body unit 101 and a protrusion 105_2 disposed in the other sidewall 101_2 of the main body unit 101.

In some embodiments, the support member 120 may have a plate form. When the support member 120 has a plate form, the support member 120 may have a large area capable of supporting a lower portion of each of strip members, and support a middle region of each of the strip members, which may greatly sag. Thus, a sag in the strip members or separation of the strip members may be prevented.

A length 120L_1 of the support member 120 in a first direction (X-axial direction) may be smaller than a length 101L_1 of the main body unit 101 in the first direction (X-axial direction). A length 120L_2 of the support member 120 obtained in a second direction (Y-axial direction) may be smaller than a length 101L_2 of the main body unit 101 in the second direction (Y-axial direction).

In some embodiments, a front side 120F of the support member 120 may be spaced a first distance FL apart from a front side F of the main body unit 101, and a rear side 120R of the support member 120 may be spaced a second distance RL apart from a rear side R of the main body unit 101. The first distance FL may be substantially equal to the second distance RL.

As in the present embodiment, when the length 120L_2 of the support member 120 in the second direction (Y-axial direction) is smaller than the length 101L_2 of the main body unit 101 in the second direction (Y-axial direction) and the front side 120F and the rear side 120R of the support member 120 are respectively spaced apart from the front side F and the rear side R of the main body unit 101, a phenomenon where the strip member is caught by the support member 120 may be reduced during the loading or unloading of the strip member.

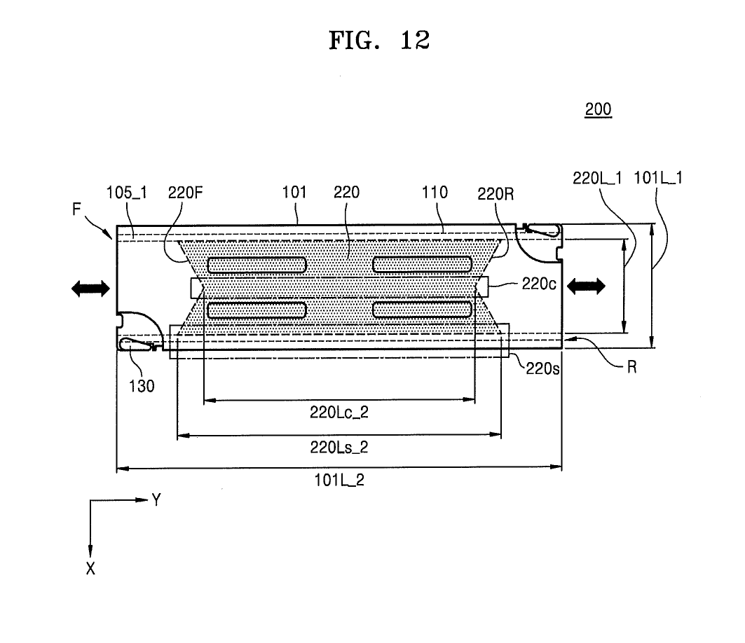

Referring to FIG. 12, a front side F and a rear side R of the magazine 200 may have an open structure to load or unload strip members. Stoppers 130 may be respectively located in one edge regions of the front side F and the rear side R of the magazine 200.

The support member 220 may be formed in the main body unit 101. The support member 220 may extend along a horizontal plane (XY plane) between a protrusion 105_1 disposed in one sidewall 101_1 of the main body unit 101 and a protrusion 105_2 disposed in the other sidewall 101_2 of the main body unit 101.

In some embodiments, the support member 220 may have a polygonal plate form.

For example, at least one of a front side 220F and a rear side 220R of the support member 220 may have a V shape in plan view. That is, a length 220Ls_2 of an edge portion 220s of the support member 220 in a second direction (Y-axial direction) may be larger than a length 220Lc_2 of a central portion 220c of the support member 220 in the second direction (Y-axial direction).

In some embodiments, a length of the support member 220 in the second direction (Y-axial direction) may gradually increase from the central portion 220c to the edge portion 220s. For example, the length of the support member 220 in the second direction (Y-axial direction) may linearly increase from the central portion 220c to the edge portion 220s.

In some embodiments, a length 220L_1 of the support member 220 in a first direction (X-axial direction) may be smaller than a length 101L_1 of the main body unit 101 in the first direction (X-axial direction). A length 220Ls_2 of the edge portion 220s of the support member 220 in the second direction (Y-axial direction) may be smaller than a length 101L_2 of the main body unit 101 in the second direction (Y-axial direction).

When at least one of the front side 220F and the rear side 220R of the support member 202 has a V shape in plan view as in the present embodiment, a phenomenon where a strip member is caught by the support member 220 may be reduced during the loading and unloading of the strip member.

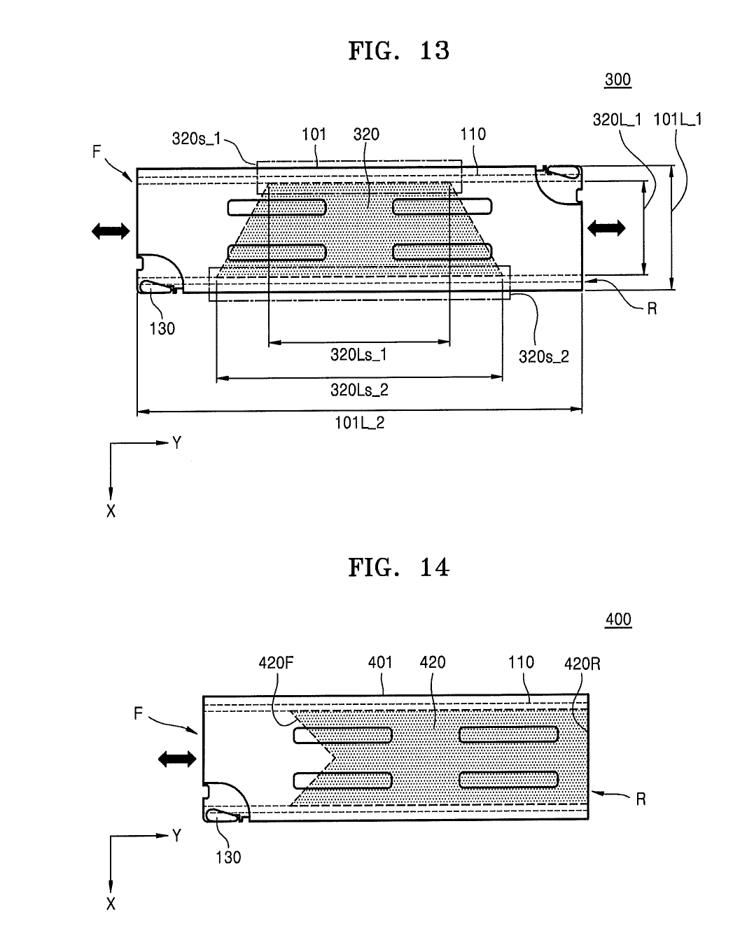

Referring to FIG. 13, the support member 320 may have a trapezoidal shape.

That is, a length 320Ls_1 of a first edge portion 320s_1 of the support member 320 in a second direction (Y-axial direction) may be smaller than a length 320Ls_2 of a second edge portion 320s_2 of the support member 320 in the second direction (Y-axial direction).

In some embodiments, a length of the support member 320 in the second direction (Y-axial direction) may gradually increase from the first edge portion 320s_1 to the second edge portion 320s_2. For example, the length of the support member 320 in the second direction (Y-axial direction) may linearly increase from the first edge portion 320s_1 to the second edge portion 320s_2.

In some embodiments, a length 320L_1 of the support member 320 in a first direction (X-axial direction) may be smaller than a length 101L_1 of the main body unit 101 in the first direction (X-axial direction). The length 320Ls_2 of the second edge portion 320s_2 of the support member 320 in the second direction (Y-axial direction) may be smaller than a length 101L_2 of the main body unit 101 in the second direction (Y-axial direction).

The support member 320 according to the present embodiment may have a trapezoidal shape, but the inventive concept is not limited thereto. The support member 320 may have various polygonal shapes, for example, a parallelogram shape.

Referring to FIG. 14, in some embodiments, only one of a front side F and a rear side R of the magazine 400 may have an open structure to load or unload strip members.

As shown in FIG. 14, when only the front side F of the magazine 400 is open and the rear side R of the magazine 400 is closed, the strip members may be loaded and unloaded through the open front side F. A stopper 130 may be formed in only one edge region of the open front side F.

When the strip members are loaded and unloaded only through the front side F, a front side 420F of the support member 420 may be spaced apart from the front side F of the main body unit 401, while a rear side 420R of the support member 420 may be in contact with the inside of the rear side R of the main body unit 401.

In some embodiments, the front side 420F of the support member 420 may have a V shape in plan view similar to the support member 220 described with reference to FIG. 12.

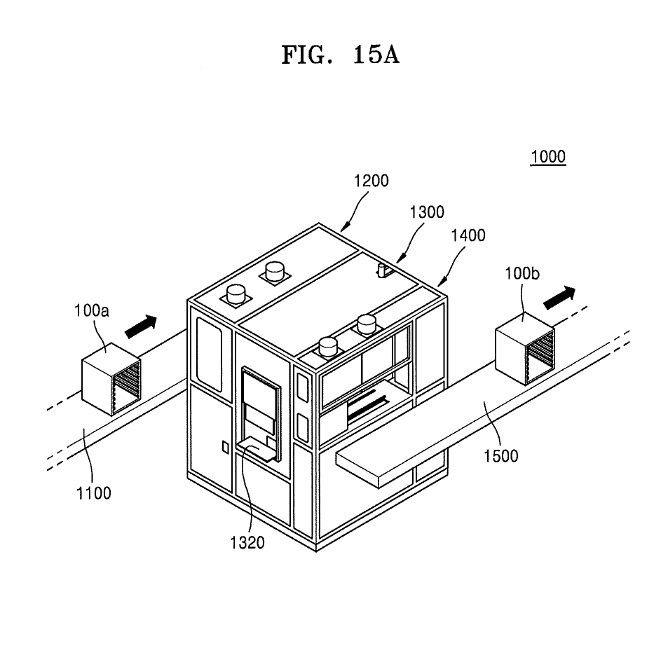

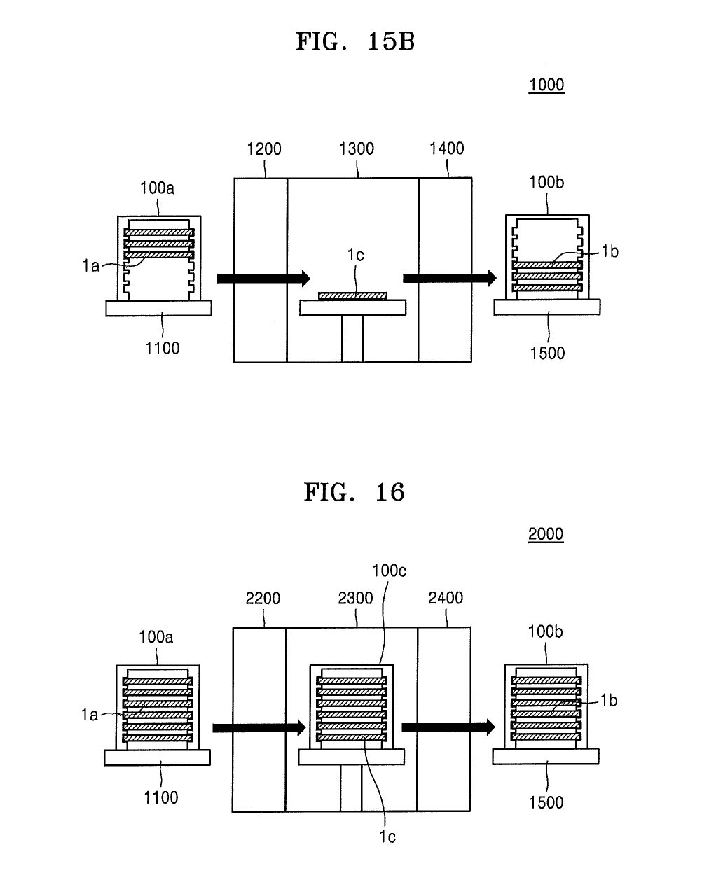

FIG. 15A is a perspective view of a process equipment 1000 including magazines 100, 200, 300, 400, 500, 600, and 700 according to example embodiments of the inventive concepts. FIG. 15B is a schematic diagram of the process equipment 1000 of FIG. 15A.

The process equipment 1000 may be an example for explaining that the magazines 100, 200, 300, 400, 500, 600, 700 according to example embodiments of the inventive concept may be applied to semiconductor package manufacturing processes. Constructions and operations of the process equipment 1000 are not limited by the present embodiments.

At least one of magazines 100a and 100b described with reference to FIGS. 15A and 15B may have a structure similar to the magazines 100, 200, 300, 400, 500, 600, and 700 described with reference to FIGS. 1 through 14.

Support members 120, 220, 320, 420, 520, 620, and 720, which may be included in the magazines 100a and 100b, are not illustrated to facilitate explanation of strip members 1a, 1b, and 1c included in the process equipment 1000.

Referring to FIGS. 15A and 15B, the process equipment 1000 may include a first magazine transfer unit 1100, a loading unit 1200, a process processing unit 1300, an unloading unit 1400, and a second magazine transfer unit 1500.

The first magazine transfer unit 1100 may serve to transfer the magazine 100a containing the strip members to the process equipment 1000 such that a process is performed on the strip members, and the second magazine transfer unit 1500 may serve to transfer the magazine 100b, which contains the strip members 1b on which a process is completely performed in the process equipment 1000, to other process equipment 1000.

In some embodiments, as shown in FIG. 15B, the loading unit 1200 may serve to load the strip members 1a contained in the magazine 100a, to the process processing unit 1300, and the unloading unit 1400 may serve to unload the strip members 1b on which a current process is completely performed in the process processing unit 1300 from the process processing unit 1300 and put the strip members into the magazine 100b.

The process processing unit 1300 may perform various processes, such as a chip bonding process, a wire bonding process, a molding process, a cleaning process, a trimming process, a forming process, a curing process, and an ink marking process.

In some embodiments, a control unit 1320 may be mounted on one side of the process processing unit 1300. The control unit 1320 may be, for example, an information management system (IMS) server. In some other embodiments, the control unit 1320 may be connected to an external host computer.

In some embodiments, the loading unit 1200, the process processing unit 1300, and the unloading unit 1400 may be formed as a unified type.

FIG. 16 is a schematic diagram of a process equipment 2000 including magazines 100, 200, 300, 400, 500, 600, and 700 according to example embodiments of the inventive concepts.

At least one of magazines 100a, 100b, and 100c described with reference to FIG. 16 may have a structure similar to the magazines 100, 200, 300, 400, 500, 600, 700 described with reference to FIGS. 1 through 14. Support members 120, 220, 320, 420, 520, 620, and 720, which may be included in the magazines 100a and 100b, are not illustrated to facilitate explanation of the strip members 1a, 1b, and 1c included in the process equipment 1000.

Referring to FIG. 16, the process equipment 2000 may include a first magazine transfer unit 1100, a loading unit 2200, a process processing unit 2300, an unloading unit 2400, and a second magazine transfer unit 1500.

The magazine 100a in which strip members 1a on which the previous process is completely performed are contained may be disposed in the first magazine transfer unit 1100. The magazine 100b in which strip members 1b on which a current process is completely performed in the process processing unit 2300 are contained may be disposed in the second magazine transfer unit 1500. The magazine 100c in which the strip members 1c on which a current process is being performed are contained may be disposed in the process processing unit 2300.

As shown in FIG. 16, the loading unit 2200 may serve to load the magazine 100a, which is transferred through the first magazine transfer unit 1100, into the process processing unit 2300. The unloading unit 2400 may serve to unload the magazine 100b on which a current process is completely performed, from the process processing unit 1300 and put the magazine 100b on the second magazine transfer unit 1500. That is, unlike the loading unit 1200 and the unloading unit 1400 described with reference to FIG. 15B, the loading unit 2200 and the unloading unit 2400 may load or unload the magazines 100a and 100b in which the strip members 1 are contained. The process processing unit 2300 may perform a unit process on the strip members 1c while the strip members 1c are being contained in the magazine 100c.

The unit process performed in the process processing unit 2300 may be, for example, a curing process, a cleaning process, or a plasma process.

When the unit process is a curing process, the process processing unit 2300 may include a chamber (not shown) and a heater (not shown). In this case, support members (not shown) of the magazine 100c may be formed of a heat-resistant material.

In some embodiments, the strip members 1c contained in the magazine 100c may be disposed in the chamber during the curing process and exposed to heat radiated from the heater, thereby causing thermal strain in the strip members 1c.

Since the magazine 100c includes support members similar to the support members 120, 220, 320, 420, 520, 620, and 720 described with reference to FIGS. 1 through 14, a sag in the strip members 1c due to thermal strain and separation of the strip members 1c may be prevented during the curing process.

When the unit process is a cleaning process, the process processing unit 2300 may include a cleaning tank (not shown) configured to clean the strip members 1c using a cleaning water and a dry tank (not shown) configured to dry the cleaned strip members 1c.

When the magazine 100c includes support members similar to the support members 120, 220, 320, 420, 520, 620, and 720 described with reference to FIGS. 1 through 14, a sag in the strip members 1c and separation of the strip members 1e may be prevented during the unloading of the magazine 100c from the cleaning tank.

While the inventive concepts have been particularly shown and described with reference to example embodiments thereof, it will be understood that various changes in form and details may be made therein without departing from the spirit and scope of the following claims.

What is claimed is:

1. A magazine comprising:
a main body unit having a front side, a rear side, a first sidewall and a second sidewall, wherein at least one of the front side and the rear side of the main body unit is open;
a plurality of slots inside each of the first and second sidewalls of the main body unit; and
at least one support member between the slots and configured to extend from the first sidewall of the main body unit to the second sidewall of the main body unit in a first direction,
wherein each of the slots may extend in a second direction perpendicular to the first direction, and a length of each of the slots in the second direction may be greater than a length of the support member in the second direction.

2. The magazine of claim 1, wherein the support member has a plate form.

3. The magazine of claim 2, wherein at least one of the front side and the rear side of the support member has a V shape in plan view.

4. A magazine comprising:
a main body unit including first and second sidewalls opposed to each other;
a plurality of slots inside each of the first and second sidewalls of the main body unit; and
a support member between the slots and including at least one support stick configured to connect insides of the first and second sidewalls of the main body unit.

5. The magazine of claim 4, wherein each of the slots extends in a first direction, and
a length of each of the slots in the first direction is greater than a length of the support member in the first direction.

6. The magazine of claim 4, further comprising a plurality of protrusions extending in the first direction inside the two sidewalls of the main body unit and to define the slots,
wherein the support member is provided on the protrusions.

7. The magazine of claim 6, wherein a thickness of each of the protrusions is greater than a thickness of the support member.

8. The magazine of claim 7, wherein a top surface of each of the protrusions is at a higher level than a top surface of the support member.

9. The magazine of claim 4, wherein a front side and a rear side of the support member are spaced apart from at least one of an open front side and an open rear side of the main body unit.

10. The magazine of claim 4, wherein the support member comprises an insulating material.

11. The magazine of claim 4, wherein the support member comprises a heat-resistant material.

12. The magazine of claim 4, wherein the support stick has a cylindrical structure or a semi-cylindrical structure.

13. The magazine of claim 4, wherein the support stick comprises an insulating wire.

14. The magazine of claim 4, wherein the support stick extends to connect a front side portion of the first sidewall of the main body unit and a rear side portion of the second sidewall of the main body unit.

15. The magazine of claim 4, wherein the at least one support stick comprises:
a first support stick configured to extend to connect a front side portion of the first sidewall of the main body unit and a rear side portion of the second sidewall of the main body unit; and
a second support stick configured to extend to connect a rear side portion of the first sidewall of the main body unit and to a front side portion of the second sidewall of the main body unit.

16. A magazine comprising:
a main body unit having an open front side, an open rear side, a first sidewall and a second sidewall opposed to the first sidewall;
first protrusions inside the first sidewall of the main body unit and second protrusions inside the second sidewall of the main body unit; and
a support member configured to connect the first and second protrusions and disposed in a plane defined by the first direction and a second direction perpendicular to the first direction.

17. The magazine of claim 16, wherein the support member includes edge portion and a central portion, and
a length of the edge portion of the support member in a first direction is larger than a length of a central portion of the support member.

18. The magazine of claim 16, wherein a length of the support member in the second direction is smaller than a length of the main body in the second direction.

19. The magazine of claim 16, wherein a front side of the support member is spaced a first distance apart from the front side of the main body unit in the first direction,
a rear side of the support member is spaced a second distance apart from the rear side of the main body unit in the first direction, and
the first distance is substantially equal to the second distance.

20. The magazine of claim 16, further comprising a stopper disposed on at least one of the front side and the rear side of the main body unit.
